(19) United States
(12) Patent Application Publication
(10) Pub. No.: US 2008/0074044 A1
(43) Pub. Date: Mar. 27, 2008

(54) Active matrix organic light emitting display and method for fabricating same

(75) Inventors: Jung-Lung Huang, Miao-Li (TW); Jia-Pang Pang, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/904,009

(22) Filed: Sep. 24, 2007

(30) Foreign Application Priority Data
Sep. 22, 2006 (TW) 95135184

(51) Int. Cl. H01L 51/54; H01L 51/56

(52) U.S. Cl. 313/504; 445/24

(57) ABSTRACT

An exemplary active matrix organic light emitting display (OLED) (10) includes a transparent insulating substrate (20), a thin film transistor (TFT) structure (245) formed on the transparent insulating substrate, and an organic emission structure (244) transparent insulating substrate. The TFT structure includes a source electrode (261), a drain electrode (262), and a passivation layer (221) configured as a cathode inter-insulator. The passivation layer covers the source electrode and the drain electrode. The organic emission structure includes a transparent electrode layer (218) directly connected with the drain electrode.

### FIELD OF THE INVENTION

The present invention relates to organic light emitting displays (OLEDs), particularly to an active matrix OLED and a method for fabricating the active matrix OLED.

### GENERAL BACKGROUND

Organic light emitting displays (OLEDs) provide images with high brightness and a wide viewing angle. Because OLEDs are self-luminous, they do not require backlights, and can be effectively used even in relatively dark environments. OLEDs can be categorized into two kinds: active matrix OLEDs and passive matrix OLEDs. Generally, active matrix OLEDs are bottom illuminated.

Referring to FIG. 13, a typical active matrix OLED includes a transparent insulating substrate 300 defining a thin film transistor (TFT) region 301 and an organic emission region 302, a TFT structure 320 corresponding to the TFT region 301, and an organic emission structure 340 corresponding to the organic emission region 302.

The TFT structure 320 includes a doped semiconductor layer 321, a first insulating layer 322, a gate electrode 323, a second insulating layer 324, a source electrode 325, a drain electrode 326, and a passivation layer 327. The doped semiconductor layer 321 is strip-shaped, and is disposed on the TFT region 301. The first insulating layer 322 covers the doped semiconductor layer 321 and the transparent insulating substrate 300. The gate electrode 323 is formed on a portion of the first insulating layer 322 that corresponds to the doped semiconductor layer 321. The second insulating layer 324 covers the gate electrode 323 and the first insulating layer 322.

The first insulating layer 322 and the second insulating layer 324 cooperatively define a first contact hole 351 and a second contact hole 353 therethrough. Thereby, the first and second contact holes 351, 353 expose two parts of the doped semiconductor 321, respectively. The source electrode 325 and the drain electrode 326 fill the two contact holes 351, 353, respectively, and each of the source and drain electrodes 325, 326 overlaps a respective portion of the second insulating layer 324. The source electrode 325 and the drain electrode 326 are electrically connected with the doped semiconductor layer 321. The passivation layer 327 covers the source electrode 325, the drain electrode 326, and the second insulating layer 324. The passivation layer 327 has a smooth upper surface, and defines a third contact hole 355. The third contact hole 355 exposes a part of the drain electrode 326.

The organic emission structure 340 includes a transparent electrode layer 328, a hole injection layer (HIL) 342, a hole transfer layer (HTL) 343, an organic emission layer (EL) 344, an electron transfer layer (ETL) 345, an electron injection layer (EIL) 346, and a cathode reflective layer 347, arranged in that order from bottom to top. The transparent electrode layer 328 covers the passivation layer 327, and is electrically connected with the drain electrode 326 in the third contact hole 355. The transparent electrode layer 328 is also used as an anode of the active matrix OLED 30.

The organic emission structure 340 further includes a cathode inter-insulator 341 on the transparent electrode layer 328, corresponding to the third contact hole 355. The cathode inter-insulator 341 is generally T-shaped in cross-section. A thickness of a horizontal top portion of the cathode inter-insulator 341 is substantially equal to a combined thickness of the HIL 342, the HTL 343, the organic EL 344, the ETL 345, the EIL 346, and the cathode reflective layer 347.

The active matrix OLED 30 needs a fabricating process to form the third contact hole 355 for electrically connecting the transparent electrode layer 328 with the drain electrode 326. Furthermore, the passivation layer 327 and the cathode inter-insulator 341 are two separate parts. Therefore two separate fabricating steps are needed to form the passivation layer 327 and the cathode inter-insulator 341. Thus the structure of the active matrix OLED 30 is somewhat complicated, and the method of fabricating the active matrix OLED 30 is correspondingly complicated.

What is needed, therefore, is a new active matrix OLED that can overcome the above-described problems. What is also needed is a method for fabricating the active matrix OLED that can overcome the above-described problems.

### SUMMARY

In one aspect, an exemplary active matrix organic light emitting display (OLED) includes a transparent insulating substrate, a thin film transistor (TFT) structure formed on the transparent insulating substrate, and an organic emission structure transparent insulating substrate. The TFT structure includes a source electrode, a drain electrode, and a passivation layer configured as a cathode inter-insulator. The passivation layer covers the source electrode and the drain electrode. The organic emission structure includes a transparent electrode layer directly connected with the drain electrode.

Other novel features and advantages will become more apparent from the following detailed description when taken in conjunction with the accompanying drawings. In the drawings, all the views are schematic.

### BRIEF DESCRIPTION OF THE DRAWINGS

FIG. 1 is an equivalent circuit diagram of part of an active matrix organic light emitting display (OLED) according to an exemplary embodiment of the present invention, the active matrix OLED including a plurality of pixel units.

FIG. 2 is an enlarged, top, plan view of one pixel unit of FIG. 1.

FIG. 3 is a flowchart summarizing an exemplary method for fabricating the active matrix OLED of FIG. 1.

FIG. 4 is a side cross-sectional view relating to a step of providing a doped semiconductor layer on a transparent insulating substrate according to the method of FIG. 3.

FIG. 5 is a side cross-sectional view relating to a step of providing a first insulating layer on the transparent insulating substrate and the doped semiconductor layer according to the method of FIG. 3.

FIG. 6 is a side cross-sectional view relating to a step of providing a gate electrode layer on the first insulating layer according to the method of FIG. 3.

FIG. 7 is a side cross-sectional view relating to a step of providing a second insulating layer on the gate electrode layer and the first insulating layer according to the method of FIG. 3.

FIG. 8 is a side cross-sectional view relating to a step of forming a first contact hole and a second contact hole through the two insulating layers according to the method of FIG. 3.

FIG. 9 is a side cross-sectional view relating to a step of providing a source electrode and a drain electrode filling the two contact holes according to the method of FIG. 3.

FIG. 10 is a side cross-sectional view relating to a step of providing a transparent electrode layer on the second insulating layer and a portion of the drain electrode according to the method of FIG. 3.

FIG. 11 is a side cross-sectional view relating to a step of providing a passivation layer on the second insulating layer, the source electrode, the drain electrode, and a portion of the transparent electrode layer according to the method of FIG. 3.

FIG. 12 is a side cross-sectional view relating to a step of providing an organic emission structure on the transparent electrode layer according to the method of FIG. 3.

FIG. 13 is a side cross-sectional view of part of a conventional active matrix OLED.

### DETAILED DESCRIPTION OF PREFERRED EMBODIMENTS

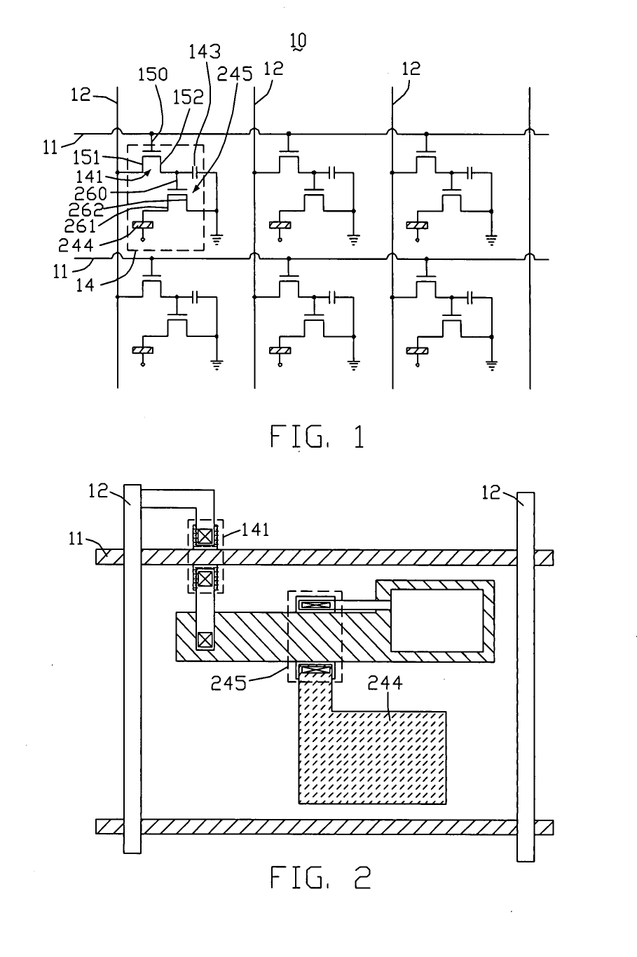

Referring to FIG. 1 and FIG. 2, certain parts of an active matrix organic light emitting display (OLED) 10 according to an exemplary embodiment of the present invention are shown. The active matrix OLED 10 includes a plurality of scan lines 11 that are parallel to each other and that each extend along a first direction, and a plurality of data lines 12 that are parallel to each other and that each extend along a second direction that is orthogonal to the first direction. A smallest rectangular area formed by any two adjacent scan lines 11 together with any two adjacent data lines 12 defines a pixel unit 14 thereat. Each pixel unit 14 includes a first thin film transistor (TFT) 141, a second TFT 245, a storage capacitor 143, and an organic emission structure 244. In the active matrix OLED 10, the first TFTs 141 operate as switching elements of the second TFTs 245, and the second TFTs 245 operate as switching elements of the organic emission structures 244. In each pixel unit 14, the storage capacitor 143 is used to store electrical power for the organic emission structure 244.

In each pixel unit 14, the first TFT 141 includes a first gate electrode 150, a first source electrode 151, and a first drain electrode 152. The second TFT 245 includes a second gate electrode 260, a second source electrode 261, and a second drain electrode 262. The first gate electrode 150 is connected with the corresponding scan line 11. The first source electrode 151 is connected with the corresponding data line 12. The first drain electrode 152 is connected with the second gate electrode 260. The second source electrode 261 is grounded. The second drain electrode 262 is connected with the organic emission structure 244. The storage capacitor 143 connects the second gate electrode 260 to ground.

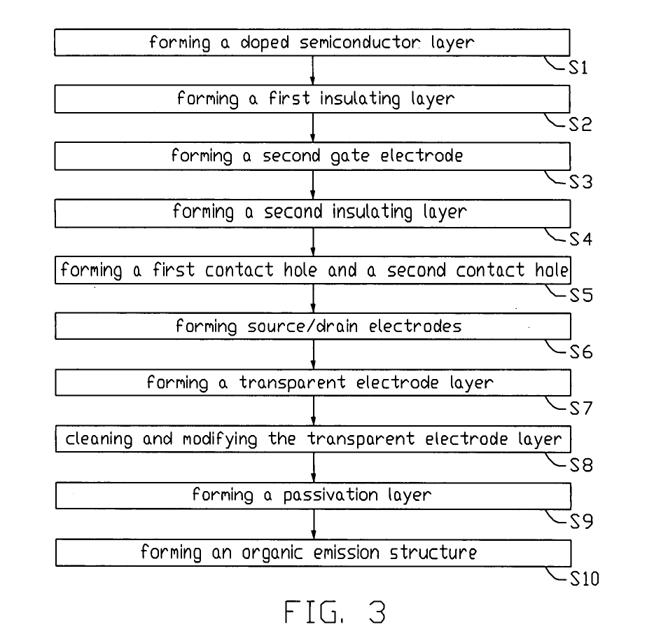

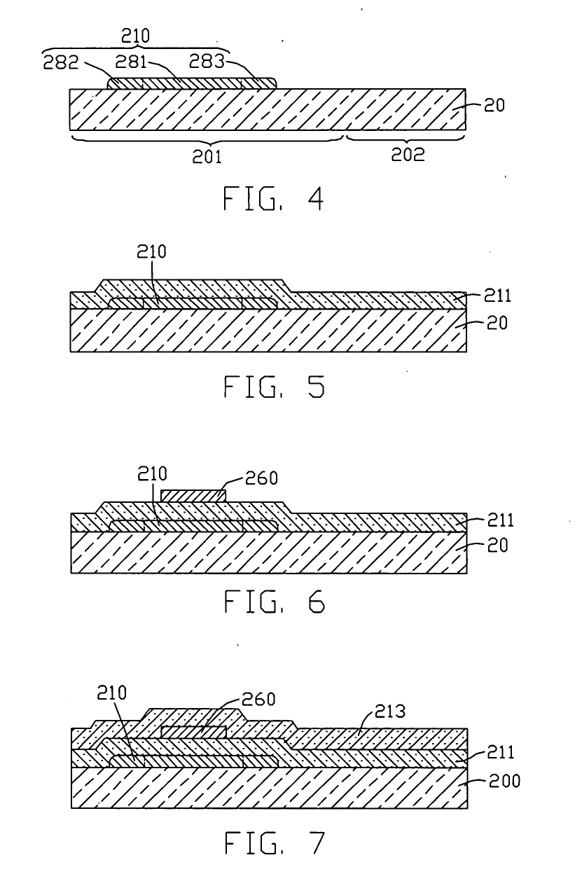

Referring to FIG. 3, this is a flowchart summarizing an exemplary method for fabricating the active matrix OLED 10. The method includes: step S1, forming a doped semiconductor layer; step S2, forming a first insulating layer; step S3, forming a second gate electrode; step S4, forming a second insulating layer; step S5, forming a first contact hole and a second contact hole; step S6, forming source/drain electrodes; step S7, forming a transparent electrode layer; step S8, cleaning and modifying the transparent electrode layer; step S9, forming a passivation layer; and step S10, forming an organic emission structure.

In step S1, referring to FIG. 4, a transparent insulating substrate 20 is provided. The transparent insulating substrate 20 may be made from glass or quartz. The transparent insulating substrate 20 includes a TFT region 201 and an organic emission region 202. A poly-silicon layer is deposited on the transparent insulating substrate 20. The poly-silicon layer is patterned into an island-shape on the TFT region 201. A middle portion of the island-shaped poly-silicon layer is doped, thereby forming an active middle portion 281. Two ends of the island-shaped poly-silicon layer which are not doped form a source region 282 and a drain region 283, respectively. The poly-silicon layer is thus defined as a doped semiconductor layer 210.

In step S2, referring to FIG. 5, a first insulating layer 211 is deposited on the doped semiconductor layer 210 and the transparent insulating substrate 20 by a chemical vapor deposition (CVD) process. The first insulating layer 211 can be made from amorphous silicon nitride (SiNx) or silicon dioxide (SiO₂).

In step S3, referring to FIG. 6, a gate metal layer and a first photo-resist layer (not shown) are sequentially formed on the first insulating layer 211. The gate metal layer can be made from material including any one or more items selected from the group consisting of aluminum (Al), molybdenum (Mo), copper (Cu), chromium (Cr), and tantalum (Ta).

An ultraviolet (UV) light source (not shown) and a first photo-mask (not shown) are used to expose the first photo-resist layer. Then the exposed first photo-resist layer is developed, thereby forming a first photo-resist pattern. Using the first photo-resist pattern as a mask, portions of the gate metal layer which are not covered by the first photo-resist pattern are etched away, thereby forming a second gate electrode 260. The first photo-resist pattern is then removed by using an acetone solution.

In step S4, referring to FIG. 7, a second insulating layer 213 is deposited on the first insulating layer 211 and the second gate electrode 260. The second insulating layer 213 can be made from amorphous silicon nitride (SiNx) or silicon dioxide (SiO₂).

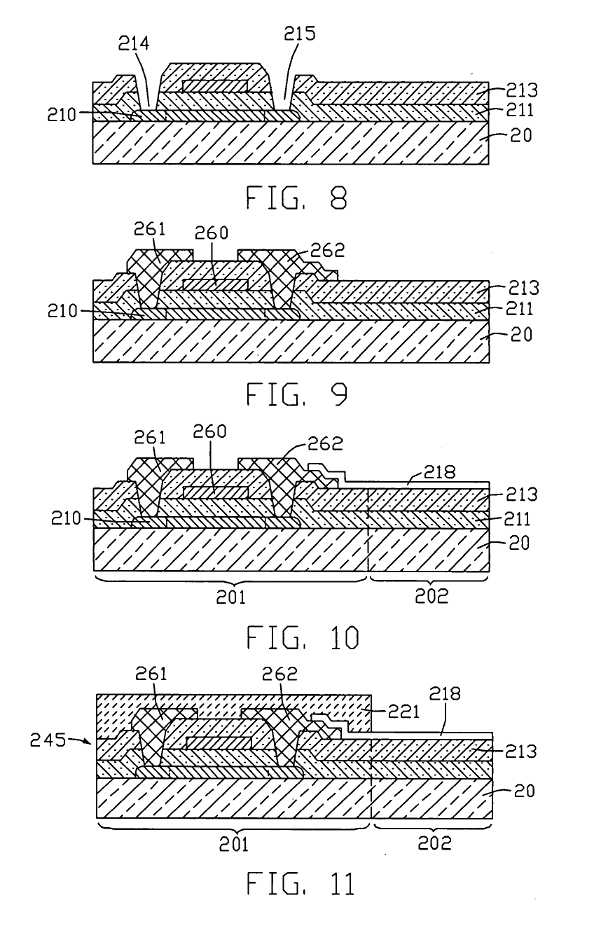

In step S5, referring to FIG. 8, a second photo-resist layer (not shown) is coated on the second insulating layer 213. The ultraviolet (UV) light source and a second photo-mask (not shown) are used to expose the second photo-resist layer. Then the exposed second photo-resist layer is developed, thereby forming a second photo-resist pattern. Using the second photo-resist pattern as a mask, portions of the second insulating layer 213 and the first insulating layer 211 which are not covered by the second photo-resist pattern are etched away. Thereby, a first contact hole 214 and a second contact hole 215 are defined through said portions, with a part of the source region 282 and a part of the drain region 283 of the doped semiconductor layer 210 being exposed. The second photo-resist pattern is then removed by using an acetone solution.

In step S6, referring to FIG. 9, a source/drain metal layer and a third photo-resist layer (not shown) are sequentially formed on the second insulating layer 213 and the doped semiconductor 210. The source/drain metal layer can be made from material including any one or more items selected from the group consisting of aluminum (Al), molybdenum (Mo), and tantalum (Ta).

The third photo-resist layer is exposed by a third photo-mask, and then is developed, thereby forming a third photo-resist pattern. Using the third photo-resist pattern as a mask, portions of the source/drain metal layer which are not covered by the third photo-resist pattern are etched away by one or more concentrated acid solutions, thereby forming a second source electrode 261 and a second drain electrode 262. The third photo-resist pattern is then removed by using an acetone solution. The second source electrode 261 and the second drain electrode 262 fill the first contact hole 214 and the second contact hole 215 respectively, and are electrically connected with the doped semiconductor layer 210. The second source electrode 261 and the second drain electrode 262 further cover a portion of the second insulating layer 213. The one or more concentrated acid solutions can for example be either or both of a nitric acid (HNO₃) solution and an acetic acid (C₂H₄O₂) solution.

In step S7, referring to FIG. 10, a transparent conductive layer (not shown) and a fourth photo-resist layer (not shown) are sequentially formed on the second source electrode 261, the second drain electrode 262, and the second insulating layer 213. The transparent conductive layer may be made from indium tin oxide (ITO) or indium zinc oxide (IZO).

The fourth photo-resist layer is exposed by a fourth photo-mask, and then is developed, thereby forming a fourth photo-resist pattern. Using the fourth photo-resist pattern as a mask, portions of the transparent conductive layer which are not covered by the fourth photo-resist pattern are etched away by a weak acid solution, thereby forming a transparent electrode layer 218. The fourth photo-resist pattern is then removed by using an acetone solution. The transparent electrode layer 218 covers a portion of the second insulating layer 213 that corresponds to the organic emission region 202. The transparent electrode layer 218 further covers a portion of the drain electrode 261, and is electrically connected with the drain electrode 261. The transparent electrode layer 218 corresponding to the organic emission region 202 also operates as an anode of the active matrix OLED 10. The acid solution can be an oxalic acid ((COOH)₂ or H₂C₂O₄) solution.

In step S8, an upper surface of the transparent electrode layer 218 is cleaned and modified by a plasma treatment.

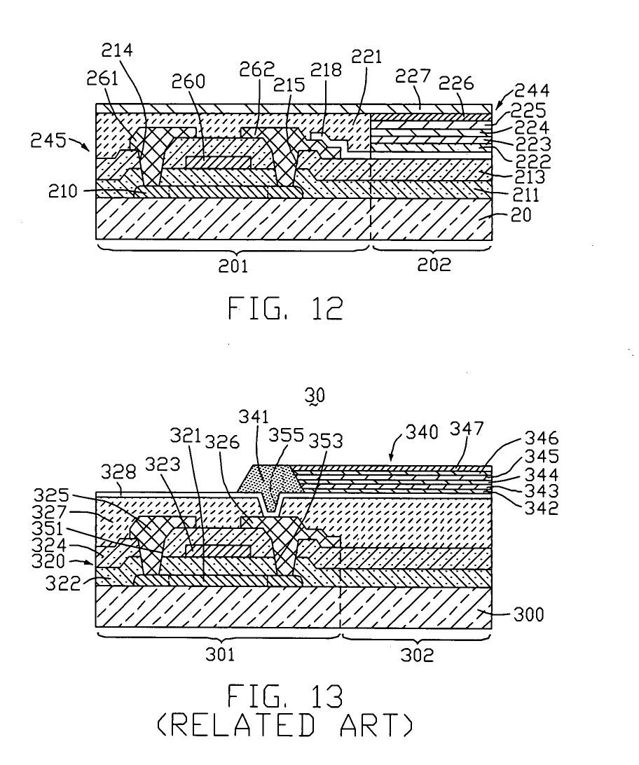

In step S9, referring to FIG. 11, a passivation layer 221 is deposited on the second source electrode 261, the second drain electrode 262, the second insulating layer 213, and the transparent electrode layer 218 by a spin coating method or a spray coating method. The passivation layer 221 has a smooth upper surface. The passivation layer 221 can be made from organic light sensitive material.

A portion of the passivation layer 221 corresponding to the organic emission region 202 is etched away by a fifth photo-mask process to expose the transparent electrode layer 218. A residual portion of the passivation layer 221 corresponding to the TFT region 201 is defined as a cathode inter-insulator 221.

After step S9 has been completed, a TFT structure 245 is formed on the TFT region 201, with the anode of the active matrix OLED 10 provided on the organic emission region 202.

In step S10, referring to FIG. 12, a hole injection layer (HIL) 222, a hole transfer layer 223 (HTL), an organic emission layer (EL) 224, an electron transfer layer (ETL) 225, and an electron injection layer (EIL) 226 are sequentially formed on the transparent electrode layer 218, in that order from bottom to top. A cathode reflective layer 227 is formed on the EIL 226 and the cathode inter-insulator 221. A combined thickness of the HIL 222, the HTL 223, the organic EL 224, the ETL 225, and the EIL 226 is substantially equal to a thickness of the cathode inter-insulator 221. Thus, an organic emission structure 244 is formed.

The HIL 222 can be made from copper phthalocyanine (CuPc). The HTL 223 can be made from polycyclic aromatic hydrocarbons (PAHs), such as polyaniline or triaromatic derivatives. The EIL 226 can be made from alkali metals or alkali earth metals with low work function, such as lithium fluoride (LiF), compounds of calcium (Ca), or magnesium (Mg). The ETL 225 can be made from aromatic compounds having great conjugate planes.

The organic EL 224 can for example be made from polymeric electroluminescence material, which is deposited by a spin on deposition (SOD) process or an inkjet printing process. The polymeric electroluminescence material can be para-phenylenevinylene (PPV). The organic EL 224 can instead be made from small molecular compounds which are deposited by a vacuum vapor deposition (VVD) process. The small molecular compounds can be diamine compounds.

Unlike with conventional active matrix OLEDs and methods for fabricating conventional active matrix OLEDs, the second drain electrode 262 of the active matrix OLED 10 is directly connected with the transparent electrode layer 218. Thus there is not need for a process of forming a contact hole in order to electrically connect the second drain electrode 262 and the transparent electrode layer 218. Furthermore, the residual portion of the passivation layer 221 used for protecting the TFT structure 245 is also used as the cathode inter-insulator 221. Thereby, there is no need for a separate process of fabricating the cathode inter-insulator 221. For these reasons, the method for fabricating the active matrix OLED 10 is simplified, and the cost of fabricating the active matrix OLED 10 is reduced. Further, the structure of the active matrix OLED is simplified.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. An active matrix organic light emitting display (OLED) comprising:
a transparent insulating substrate;
a thin film transistor (TFT) structure formed on the transparent insulating substrate, the TFT structure comprising:
a source electrode,
a drain electrode, and
a passivation layer covering the source electrode and the drain electrode, the passivation layer configured as a cathode inter-insulator; and
an organic emission structure formed on the transparent insulating substrate, the organic emission structure comprising a transparent electrode layer directly connected with the drain electrode.

2. The active matrix OLED as claimed in claim 1, wherein the TFT structure further comprises a doped semiconductor layer formed on the transparent insulating substrate, a first insulating layer formed on the doped semiconductor layer and the transparent insulating substrate, a gate electrode formed on a portion of the first insulating layer that corresponds to the doped-semiconductor layer, and a second insulating layer formed on the gate electrode and the first insulating layer.

3. The active matrix OLED as claimed in claim 2, wherein the first insulating layer and the second insulating layer cooperatively define two contact holes, and the source electrode and the drain electrode which are formed on the second insulating layer are electrically connected with the doped semiconductor through the two contact holes, respectively.

4. The active matrix OLED as claimed in claim 2, wherein the transparent electrode layer is formed on the second insulating layer and a part of the drain electrode.

5. The active matrix OLED as claimed in claim 1, wherein the source electrode and the drain electrode are made from material comprising any one or more items selected from the group consisting of aluminum, molybdenum, and tantalum.

6. The active matrix OLED as claimed in claim 1, wherein the organic emission structure further comprises a hole injection layer formed on the transparent electrode layer, a hole transfer layer formed on the hole injection layer, an organic emission layer formed on the hole transfer layer, an electron transfer layer formed on the organic emission layer, an electron injection layer formed on the electron transfer layer, and a cathode reflective layer covering the electron injection layer and the passivation layer.

7. The active matrix OLED as claimed in claim 6, wherein a combined thickness of the hole injection layer, the hole transfer layer, the organic emission layer, the electron transfer layer, and the electron injection layer is substantially equal to a thickness of the passivation layer.

8. The active matrix OLED as claimed in claim 6, wherein the hole injection layer is made from copper phthalocyanine.

9. The active matrix OLED as claimed in claim 6, wherein the hole transfer layer is made from at least one item selected from the group consisting of polyaniline and triaromatic derivatives.

10. The active matrix OLED as claimed in claim 6, wherein the organic emission layer is made from polymeric electroluminescence material.

11. The active matrix OLED as claimed in claim 6, wherein the organic emission layer is made from one or more diamine compounds.

12. The active matrix OLED as claimed in claim 6, wherein the electron injection layer is made from alkali metals or alkali earth metals with low work function.

13. A method for fabricating an active matrix organic light emitting display (OLED), the method comprising:
providing a transparent insulating substrate;
forming a thin film transistor (TFT) structure on the transparent insulating substrate, comprising:
forming a source electrode and a drain electrode, and
forming a passivation layer covering the source electrode and the drain electrode;
forming an organic emission structure on the transparent insulating substrate, comprising:
forming a transparent electrode layer directly connected to the drain electrode.

14. The method as claimed in claim 13, wherein the step of forming the TFT structure further comprises: forming a doped semiconductor layer, a first insulating layer, a gate electrode, a second insulating layer in sequence, and forming the source electrode and the drain electrode on the second insulating layer.

15. The method as claimed in claim 14, wherein the step of forming the doped semiconductor layer comprises: depositing a poly-silicon layer on the transparent insulating substrate, patterning the poly-silicon layer, doping a middle portion of the poly-silicon layer to form an active layer.

16. The method as claimed in claim 14, wherein the step of forming the gate electrode comprises: depositing a gate mental layer on the first insulating layer, and patterning the gate mental layer to form a gate electrode by a photolithograph process.

17. The method as claimed in claim 14, wherein the step of forming the second insulating layer comprises: forming two contact holes each cutting through the first insulating layer and the second insulating layer to expose the doped semiconductor layer, respectively.

18. The method as claimed in claim 17, wherein the step of forming the source electrode and the drain electrode comprises: depositing a source/drain mental layer on the second insulating layer and the doped semiconductor layer, and patterning the source/drain mental layer to form the source electrode and the drain electrode corresponding to the two contact holes, respectively.

19. The method as claimed in claim 13, wherein the step of forming the organic emission structure further comprises: forming a hole injection layer, a hole transfer layer, an organic emission layer, an electron transfer layer, and an electron injection layer in sequence on the transparent electrode layer, and forming a cathode reflective layer on the electrode injection layer and the passivation layer.

20. The method as claimed in claim 19, wherein the organic emission layer is made from polymer electroluminescence material, and the hole injection layer is made from copper phthalocyanine, and the hole transfer layer is made from polyaniline or triaromatic derivatives, and the electron injection layer is made from alkali metals or alkali earth metals.
